(19) United States
(12) Patent Application Publication
(10) Pub. No.: US 2023/0189664 A1
(43) Pub. Date: Jun. 15, 2023

(54) Qubit Capacitor Trimming for Frequency Tuning

(71) Applicant: International Business Machines Corporation, Armonk, NY (US)

(72) Inventors: Antoin Hervier, Yorktown Heights, NY (US); Oliver Dial, Yorktown Heights, NY (US); Ken Perez, Yorktown Heights, NY (US); Mary Beth Rothwell, Yorktown Heights, NY (US)

(21) Appl. No.: 17/644,447

(22) Filed: Dec. 15, 2021

(51) Int. Cl. H01L 39/24

(52) U.S. Cl. CPC H01L 39/2493

(57) ABSTRACT

A method comprising forming capacitor pads for a qubit on a silicon wafer. Applying a resist layer on top of the capacitor pads. Pattern the resist layer to expose a portion of the capacitor pads. Utilizing an electron beam to remove the exposed portion of the capacitor.

### STATEMENT REGARDING FEDERALLY SPONSORED RESEARCH OR DEVELOPMENT

This invention was made with U.S. Government support. The U.S. Government has certain rights in this invention.

### BACKGROUND

The present invention relates to qubit, and more specifically, to tuning a frequency of a qubit by selectively trimming a structured capacitor.

Superconducting qubits with ever-increasing coherence times show great promise for future quantum computing systems. In large multi-qubit systems, a qubit's resonant frequency must be precisely controlled in order to avoid signaling collisions.

### BRIEF SUMMARY

Additional aspects and/or advantages will be set forth in part in the description which follows and, in part, will be apparent from the description, or may be learned by practice of the invention.

A method comprising forming capacitor pads for a qubit on a silicon wafer.

Applying a resist layer on top of the capacitor pads. Pattern the resist layer to expose a portion of the capacitor pads. Utilizing an electron beam to remove the exposed portion of the capacitor.

A method comprising forming a first capacitor pad for a qubit on a silicon wafer. Forming a second capacitor pad for the qubit on the silicon wafer. Applying a resist layer on top of the first capacitor pad and to the top of the second capacitor pad. Pattern the resist layer to expose a portion of the first capacitor pad and utilizing an electron beam to remove the exposed portion of the first capacitor pad.

A method comprising forming a first capacitor pad for a qubit on a silicon wafer. Forming a second capacitor pad for the qubit on the silicon wafer and forming a Josephson Junction to connected the first capacitor pad to the second capacitor pad. Applying a resist layer on top of the first capacitor pad and to the top of the second capacitor pad. Pattern the resist layer to expose a portion of the first capacitor pad and to expose a portion of the second capacitor pad, wherein the dimensions of the exposed portion of the first capacitor pad and the dimension of the exposed portion of the second capacitor pads are different. Utilizing an electron beam to remove the exposed portion of the first capacitor pad and to remove a portion of the second capacitor pads.

### BRIEF DESCRIPTION OF THE DRAWINGS

The above and other aspects, features, and advantages of certain exemplary embodiments of the present invention will be more apparent from the following description taken in conjunction with the accompanying drawings, in which:

FIG. 1 represents a top down view of qubit, according to an example embodiment.

FIG. 2 represents a top down view of a qubit that has been trimmed, according to an example embodiment.

FIG. 3 represents cross-section A of the capacitor, according to an example embodiment.

FIG. 4 represents a cross-section A view depicting forming a lithography layer, according to an example embodiment.

FIG. 5 represents a cross-section A view depicting the trimmed capacitor, according to an example embodiment.

FIG. 6 represents a flow diagram method for trimming a capacitor of a qubit, according to an example embodiment.

Elements of the figures are not necessarily to scale and are not intended to portray specific parameters of the invention. For clarity and ease of illustration, dimensions of elements may be exaggerated. The detailed description should be consulted for accurate dimensions. The drawings are intended to depict only typical embodiments of the invention, and therefore should not be considered as limiting the scope of the invention. In the drawings, like numbering represents like elements.

### DETAILED DESCRIPTION

Exemplary embodiments now will be described more fully herein with reference to the accompanying drawings, in which exemplary embodiments are shown. This disclosure may, however, be embodied in many different forms and should not be construed as limited to the exemplary embodiments set forth herein. Rather, these exemplary embodiments are provided so that this disclosure will be thorough and complete and will convey the scope of this disclosure to those skilled in the art. In the description, details of well-known features and techniques may be omitted to avoid unnecessarily obscuring the presented embodiments.

For purposes of the description hereinafter, terms such as “upper”, “lower”, “right”, “left”, “vertical”, “horizontal”, “top”, “bottom”, and derivatives thereof shall relate to the disclosed structures and methods, as oriented in the drawing figures. Terms such as “above”, “overlying”, “atop”, “on top”, “positioned on” or “positioned atop” mean that a first element, such as a first structure, is present on a second element, such as a second structure, wherein intervening elements, such as an interface structure may be present between the first element and the second element. The term “direct contact” means that a first element, such as a first structure, and a second element, such as a second structure, are connected without any intermediary conducting, insulating or semiconductor layers at the interface of the two elements. As used herein, the term “same” when used for comparing values of a measurement, characteristic, parameter, etc., such as “the same width,” means nominally identical, such as within industry accepted tolerances for the measurement, characteristic, parameter, etc., unless the context indicates a different meaning. As used herein, the terms “about,” “approximately,” “significantly, or similar terms, when used to modify physical or temporal values, such as length, time, temperature, quantity, electrical characteristics, superconducting characteristics, etc., or when such values are stated without such modifiers, means nominally equal to the specified value in recognition of variations to the values that can occur during typical handling, processing, and measurement procedures. These terms are intended to include the degree of error associated with measurement of the physical or temporal value based upon the equipment available at the time of filing the application, or a value within accepted engineering tolerances of the stated value. For example, the term “about” or similar can include a range of ±8% or 5%, or 2% of a given value. In one aspect, the term “about” or similar means within 10% of the specified numerical value. In another aspect, the term “about” or similar means within 5% of the specified numerical value. Yet, in another aspect, the term “about” or similar means within 10, 9, 8, 7, 6, 5, 4, 3, 2, or 1% of the specified numerical value. In another aspect, these terms mean within industry accepted tolerances.

For the clarity of the description, and without implying any limitation thereto, illustrative embodiments may be described using simplified diagrams. In an actual fabrication, additional structures that are not shown or described herein, or structures different from those shown and described herein, may be present without departing from the scope of the illustrative embodiments.

Differently patterned portions in the drawings of the example structures, layers, and formations are intended to represent different structures, layers, materials, and formations in the example fabrication, as described herein. A specific shape, location, position, or dimension of a shape depicted herein is not intended to be limiting on the illustrative embodiments unless such a characteristic is expressly described as a feature of an embodiment. The shape, location, position, dimension, or some combination thereof, are chosen only for the clarity of the drawings and the description and may have been exaggerated, minimized, or otherwise changed from actual shape, location, position, or dimension that might be used in actual fabrication to achieve an objective according to the illustrative embodiments.

An embodiment when implemented in an application causes a fabrication process to perform certain steps as described herein. The steps of the fabrication process are depicted in the several figures. Unless such a characteristic is expressly described as a feature of an embodiment, not all steps may be necessary in a particular fabrication process; some fabrication processes may implement the steps in different order, combine certain steps, remove or replace certain steps, or perform some combination of these and other manipulations of steps, without departing the scope of the illustrative embodiments.

The illustrative embodiments are described with respect to certain types of materials, electrical properties, structures, formations, layers orientations, directions, steps, operations, planes, dimensions, numerosity, data processing systems, environments, and components. Unless such a characteristic is expressly described as a feature of an embodiment, any specific descriptions of these and other similar artifacts are not intended to be limiting to the invention; any suitable manifestation of these and other similar artifacts can be selected within the scope of the illustrative embodiments.

The illustrative embodiments are described using specific designs, architectures, layouts, schematics, and tools only as examples and are not limiting to the illustrative embodiments. The illustrative embodiments may be used in conjunction with other comparable or similarly purposed designs, architectures, layouts, schematics, and tools.

For the sake of brevity, conventional techniques related to microelectronic fabrication may or may not be described in detail herein. Moreover, the various tasks and process steps described herein can be incorporated into a more comprehensive procedure or process having additional steps or functionality not described in detail herein. In particular, various steps in the manufacture of microelectronic devices may be well known and so, in the interest of brevity, many conventional steps may only be mentioned briefly or may be omitted entirely without providing the well-known process details.

In the following descriptions, the term length applies to dimensional characteristics along the x-axis.

In the following descriptions, the term width applies to dimensional characteristics along the y-axis.

In the following descriptions, the term thickness applies to dimensional characteristics along the z-axis.

In the interest of not obscuring the presentation of embodiments of the present invention, in the following detailed description, some processing steps or operations that are known in the art may have been combined together for presentation and for illustration purposes and in some instances may have not been described in detail. In other instances, some processing steps or operations that are known in the art may not be described at all. It should be understood that the following description is rather focused on the distinctive features or elements of various embodiments of the present invention.

Various processes used to form a micro-chip that will be packaged into an integrated circuit (IC) fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device.

Reference will now be made in detail to the embodiments of the present invention, examples of which are illustrated in the accompanying drawings, wherein like reference numerals refer to like elements throughout. Embodiments of the invention are generally directed tuning the frequency of a qubit by trimming at least one capacitor pad of the qubit. A superconducting transmon qubit is comprised of two superconducting metal electrodes (plates) that form a planar capacitor which is coupled to a Josephson junction. The qubit characteristic frequency is determined by the capacitance between the metal electrodes and the inductance of the Josephson junction. The capacitance is a function the metal electrode size, shape and the separation distance. Due to the small size of the qubit's Josephson junction and related semiconductor process variabilities, it is difficult to control the qubit's ‘as fabricated’ resonant frequency. Typically, qubit “as fabricated” frequencies deviate by 5 to 10% from the desired target value.

In multi-qubit devices, each qubit is engineered with its own distinct frequency so that it can be addressed and manipulated independently from the others. This requires fabricating qubits within a target frequency range. The larger the number of qubits, the narrower that range becomes, and the more challenging it is to avoid qubit frequency collisions. These collisions lead to unwanted interactions between the qubits which introduces errors into the system.

There are several factors that contribute to the final discrepancy between target frequency and actual frequency. These include the limitations of the lithographic process, reactive ion etching bias, the uneven grain structure within the layers that form the Josephson Junction, or poor control of the process of tunneling oxide formation, and of thermal or chemical processing, etc.

Efforts to improve frequency targeting focus on these various factors. The process described here occurs as a final step in the fabrication process, prior to bonding and packaging. Josephson junctions are fabricated with a target nominal frequency. This frequency has to be compatible with the constraints of the microwave pulses used to address the qubits. The frequencies of the different qubits on the chip also have to be sufficiently distinct to avoid unwanted qubit-qubit interactions. Each step in the fabrication process contributes to broadening the qubit frequency distribution. The typical junction deviates from its target frequency by roughly 0.5 GHz. The qubit frequency is proportional to R−1/2, where R is the junction resistance. Resistance measurements can be used to predict qubit frequency with a precision of roughly 0.1 GHz (this can be improved with better characterization of the silicon substrate used). If the predicted frequency value is off target by more than 0.2 GHz, the dimensions of the qubit's capacitors can be modified, which changes the qubit's frequency, bringing it closer to target.

The present invention aims to correct the qubit frequency after the Josephson Junction has been fabricated. The frequency of the qubit is altered by changing the dimensions of the qubit capacitors. This is achieved by removing a portion of material from one of both capacitors that make up the qubit. The superconducting metal electrodes (the capacitor plates) are trimmed to remove a portion of the material that comprises the capacitor plate. To achieve this, the wafer is subjected to an additional electron beam lithography step. This can be done with a layer of PMMA, or any other electron beam sensitive resist. The pattern applied exposes a portion of each capacitor. The area of this exposed region is specific to each qubit, and calculated based on the difference between target frequency and actual frequency.

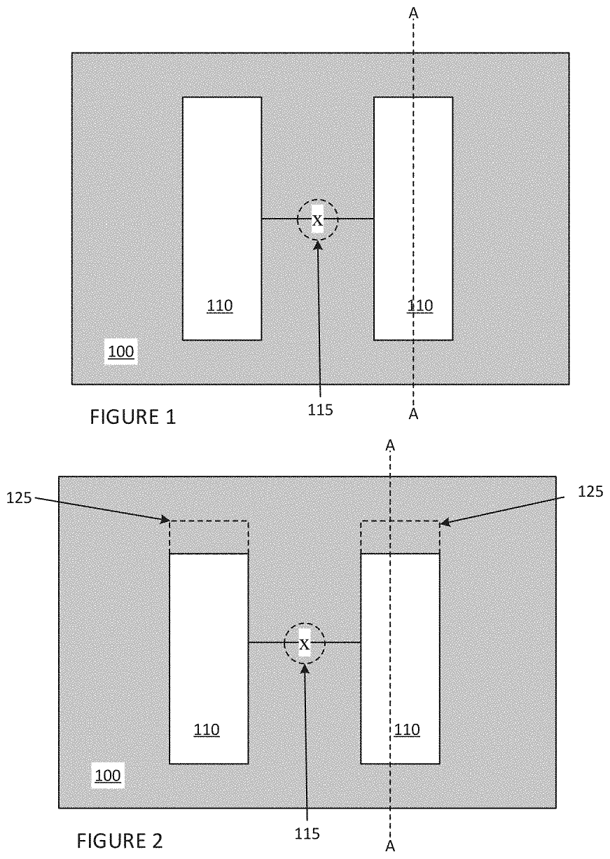

FIG. 1 represents a top down view of qubit that has trimmable sections, according to an example embodiment. The qubit is located on a substrate 100, and the qubit includes two metal plates 110, and a Josephson Junction 115. The metal plates 110 are comprised of a superconducting metal, for example, Nb or Al.

FIG. 2 represents a top down view of a qubit that has been trimmed, according to an example embodiment. Dashed box 125 indicates where a portion of the metal plates 110 was trimmed. The amount of metal trimmed can vary from qubit to qubit based on the frequency deviation of the qubit. The amount of material that is removed from the metal plates 110 can vary on the same qubit. For example, one metal plate 110 has a first portion removed and the second metal plate 110 has a second portion removed. The first portion can be greater than, equal to, or less than the second portion. The trimming of the metal plates 110 allows for correcting the deviation of the qubit frequency caused by manufacturing the qubit. Therefore, the trimming is conducting as a final step in the fabrication process, prior to bonding and packaging.

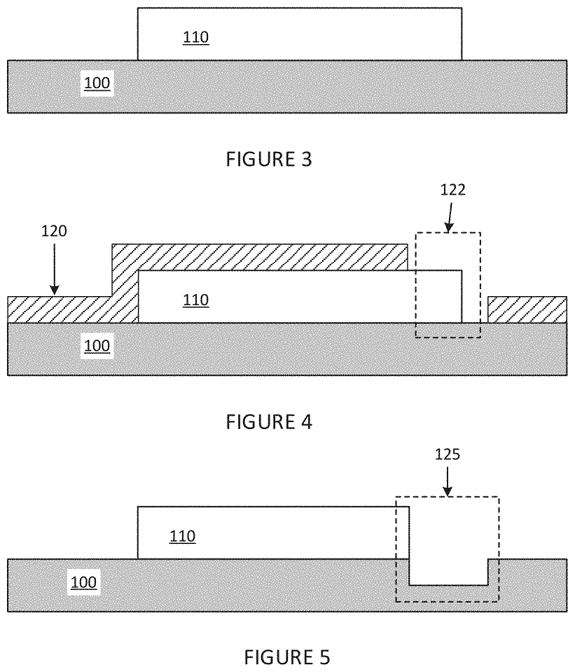

FIG. 3 represents cross-section A of the capacitor, according to an example embodiment. FIG. 3 illustrates the substrate 100 and one of the metal plates 110 that comprise the qubit. FIG. 4 represents a cross-section A view depicting forming a lithography layer, according to an example embodiment. As a final fabrication step, the frequency of the qubit it calculated and the deviation from the desired frequency is determined. The amount of material of the metal plate 110 that needs to be removed to correct the frequency deviation is determined. A lithography layer 120 is formed on top of the substrate 100 and on top of the metal plates 110. The lithography layer 120 is patterned to expose a portion of the metal plate 110 as illustrated by dashed box 122. The amount of the exposed portion of the metal plate 110 is equal to the amount of the material needed to be removed to correct for the frequency deviation.

FIG. 5 represents a cross-section A view depicting the trimmed capacitor, according to an example embodiment. The exposed portion 122 of the metal plate 110 is etched, for example, by electron beam etching to remove the exposed portion 122. Dashed box 125 illustrates where the portion of the metal plate 110 was removed. A portion of the substrate 100 is also removed to ensure that the portion of the metal plate 110 to removed is completely removed. The capacitance of the qubit is reduced such that the frequency is now closer to its intended value.

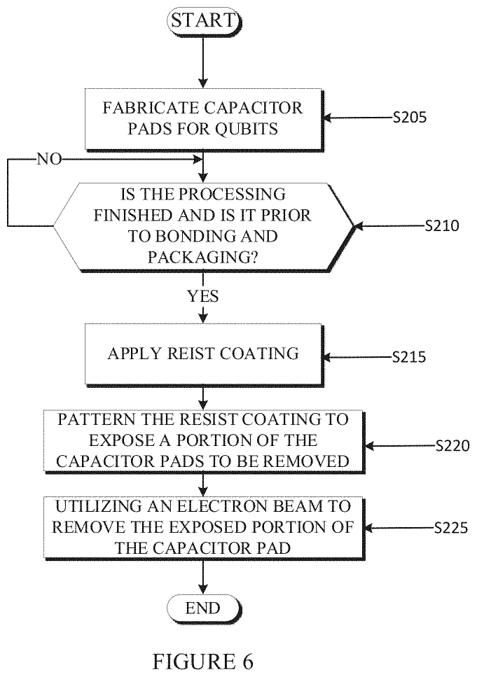

FIG. 6 represents a flow diagram method for trimming a capacitor of a qubit, according to an example embodiment. The qubit is fabricated on a substrate, where the qubit is comprised of at least two capacitor metal plates 110 (S205). Is the qubit chip finished processing and is it prior to bonding and packaging (S210), if not, wait till it is done. If yes, determine the deviation of the qubit frequency, i.e., the difference between the desired and the actual frequency. Determine how much of the material of the metal plates 110 needs to be removed to correct for the deviation of the qubit frequency. Apply a lithography layer 120 or a resist coating on top of the substrate 100 and the metal plates 110 (S215). Pattern the lithography layer 1200 to expose a portion of the metal plate 110 (S220). Etching the metal plate 110 to remove the exposed portion of the metal plate 110 (S225).

While the invention has been shown and described with reference to certain exemplary embodiments thereof, it will be understood by those skilled in the art that various changes in form and details may be made therein without departing from the spirit and scope of the present invention as defined by the appended claims and their equivalents.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the one or more embodiment, the practical application or technical improvement over technologies found in the marketplace, or to enable others of ordinary skill in the art to understand the embodiments disclosed herein.

What is claimed is:

1. A method comprising:
forming capacitor pads for a qubit on a silicon wafer;
applying a resist layer on top of the capacitor pads;
pattern the resist layer to expose a portion of the capacitor pads; and
utilizing an electron beam to remove the exposed portion of the capacitor.

2. The method of claim 1, wherein the electron beam further removes a portion of the silicon wafer below the exposed portion of the capacitor pad to ensure that complete removal of the exposed portion of the capacitor pad.

3. The method of claim 1, further comprising:
determining a manufacture resonate frequency for the qubit; and
determining an amount the manufacture resonate frequency deviates from a desired resonate frequency for the qubit.

4. The method of claim 3, further comprising:
determining an amount of material to be remove from the capacitor pads to adjust the resonate frequency of the qubit from the manufacture resonate frequency to the desired resonate frequency to the desired resonate frequency.

5. The method of claim 4, wherein the exposed portion of the capacitor pads is equal to the determined amount of material to be removed to adjust the resonate frequency of the qubit.

6. A method comprising:
forming a first capacitor pad for a qubit on a silicon wafer;
forming a second capacitor pad for the qubit on the silicon wafer;
applying a resist layer on top of the first capacitor pad and to the top of the second capacitor pad;
pattern the resist layer to expose a portion of the first capacitor pad; and
utilizing an electron beam to remove the exposed portion of the first capacitor pad.

7. The method of claim 6, wherein the electron beam further removes a portion of the silicon wafer below the exposed portion of the first capacitor pad to ensure that complete removal of the exposed portion of the first capacitor pad.

8. The method of claim 1, further comprising:
determining a manufacture resonate frequency for the qubit; and
determining an amount the manufacture resonate frequency deviates from a desired resonate frequency for the qubit.

9. The method of claim 8, further comprising:
determining an amount of material to be remove from the first capacitor pad to adjust the resonate frequency of the qubit from the manufacture resonate frequency to the desired resonate frequency to the desired resonate frequency.

10. The method of claim 9, wherein the exposed portion of the first capacitor pad is equal to the determined amount of material to be removed to adjust the resonate frequency of the qubit.

11. The method of claim 9, further comprising:
pattern the resist layer to expose a portion of the second capacitor pad; and
utilizing an electron beam to remove the exposed portion of the second capacitor pad.

12. The method of claim 11, further comprising:
determining an amount of material to be remove from the second capacitor pad to adjust the resonate frequency of the qubit from the manufacture resonate frequency to the desired resonate frequency.

13. The method of claim 12, wherein the exposed portion of the first capacitor pad and the exposed portion of the second capacitor pad is equal to the determined amount of material to be removed to adjust the resonate frequency of the qubit to the desired resonate frequency.

14. A method comprising:
forming a first capacitor pad for a qubit on a silicon wafer;
forming a second capacitor pad for the qubit on the silicon wafer;
forming a Josephson Junction to connected the first capacitor pad to the second capacitor pad;
applying a resist layer on top of the first capacitor pad and to the top of the second capacitor pad;
pattern the resist layer to expose a portion of the first capacitor pad and to expose a portion of the second capacitor pad, wherein the dimensions of the exposed portion of the first capacitor pad and the dimension of the exposed portion of the second capacitor pads are different; and
utilizing an electron beam to remove the exposed portion of the first capacitor pad and to remove a portion of the second capacitor pads.

15. The method of claim 14, wherein the electron beam further removes a portion of the silicon wafer below the exposed portion of the first capacitor pad and below the exposed portion of the second capacitor pad to ensure that complete removal of the exposed portion of the first capacitor pad.

16. The method of claim 1, further comprising:
determining a manufacture resonate frequency for the qubit; and
determining an amount the manufacture resonate frequency deviates from a desired resonate frequency for the qubit.

17. The method of claim 16, further comprising:
determining a total amount of material to be removed from the first capacitor pad and the amount of material to remove from the second capacitor pad to adjust the resonate frequency of the qubit from the manufacture resonate frequency to the desired resonate frequency to the desired resonate frequency.

18. The method of claim 17, further comprising:
determining an amount of material to remove from the first capacitor pad;
determining an amount of material to remove from the second capacitor pad;
wherein the amount of material to remove from the first capacitor pad and the amount of material to remove from the second capacitor pad is equal to the determine total amount of material to be removed from the first capacitor pad and the amount of material to remove from the second capacitor pad.

19. The method of claim 18, wherein the amount of material to remove from the first capacitor pad is different than the determined amount of material to remove from the second capacitor pad.
